(19) United States
(12) Patent Application Publication
(10) Pub. No.: US 2021/0188122 A1
(43) Pub. Date: Jun. 24, 2021

(54) Vehicle and Control Method Thereof

(71) Applicants: Hyundai Motor Company, Seoul (KR); Kia Motors Corporation, Seoul (KR)

(72) Inventors: Jin Kim, Suwon-si (KR); HanYoung Park, Anyang-si (KR)

(21) Appl. No.: 16/919,494

(22) Filed: Jul. 2, 2020

(30) Foreign Application Priority Data
Dec. 18, 2019 (KR) 10-2019-0169462

(51) Int. Cl. B60L 58/15; B60L 53/20; B60L 50/61

(52) U.S. Cl. CPC B60L 58/15; B60L 53/20; B60L 2240/665; B60L 2240/54; B60L 2240/662; B60L 50/61

(57) ABSTRACT

A vehicle includes a battery, a power supply device configured to supply charging power to the battery, a power generation device provided to be detachable, a battery sensor configured to sense a state of charge of the battery, and a controller configured to determine whether the power generation device is mounted based on the state of charge of the battery, adjust a charging target amount of the battery in a direction to decrease when the power generation device is mounted and control the power supply device while driving based on the adjusted charging target amount.

### CROSS-REFERENCE TO RELATED APPLICATIONS

This application claims priority to Korean Patent Application No. 10-2019-0169462, filed in the Korean Intellectual Property Office on Dec. 18, 2019, which application is hereby incorporated herein by reference.

### TECHNICAL FIELD

The disclosure relates to a vehicle and a control method thereof.

### BACKGROUND

Recently, there is an increasing demand to apply energy harvesting to vehicles. Accordingly, more and more users are mounting a power generation device for energy harvesting in a vehicle.

However, when charging a battery based on a power generation device for energy harvesting, there is a problem in that the vehicle cannot manage the battery charge amount because there is no information about the power generation device.

Specifically, when a power generation device is mounted in an existing vehicle that charges a battery according to an alternator or converter, there may be a problem in managing the battery charge amount by additional battery charging by the power generation device.

### SUMMARY

The disclosure relates to a vehicle and a control method thereof. Particular embodiments relate to a vehicle that can be equipped with a power generation device and a control method thereof.

Therefore, an embodiment of the disclosure provides a vehicle for controlling a battery charge amount by determining whether a power generation device for energy harvesting is installed, and a control method thereof.

In accordance with one embodiment of the disclosure, a vehicle includes a battery, a power supply device configured to supply charging power to the battery, a power generation device provided to be detachable, a battery sensor configured to sense the state of charge of the battery, and a controller configured to determine whether the power generation device is mounted based on the state of charge of the battery, adjust the charging target amount of the battery in a direction to decrease when the power generation device is mounted and control the power supply device while driving based on the adjusted charging target amount.

The power supply device may be an alternator configured to supply charging power to the battery based on the rotational force of the engine.

The power supply device may be a converter configured to supply charging power to the battery by converting a high voltage power of a main battery into low voltage power.

The vehicle may further include a driving detecting sensor configured to detect a driving state of the vehicle, and the controller may be configured to determine that the power generation device is mounted when the vehicle is parked and the battery is charged.

The vehicle may further include an illuminance sensor configured to detect illuminance, and a temperature sensor configured to detect external temperature.

The controller may be configured to control to prevent overcharging of the battery when the vehicle is parked and the battery is fully charged.

The controller may be configured to control a switch between the battery and the power generation device to prevent overcharging of the battery.

The controller may be configured to determine an electric power load based on at least one of the illuminance and the external temperature and control the battery to supply power to the electric power load to prevent overcharging of the battery.

The controller may be configured to determine the amount of power generation per hour of the power generation device when the vehicle is parked and the battery is charged.

The controller may be configured to determine the amount of power generation per hour according to at least one of the illuminance and the external temperature.

The controller may be configured to adjust the charging target amount of the battery in a direction to decrease in proportion to the amount of power generation per hour of the power generation device.

The controller may be configured to determine an adjustment amount of a charging target amount of the battery based on at least one of the illuminance and the external temperature.

In accordance with another embodiment of the disclosure, a control method of a vehicle including a battery, a power supply device configured to supply charging power to the battery, a power generation device provided to be detachable and a battery sensor configured to sense the state of charge of the battery is provided. The control method includes determining whether the power generation device is mounted based on the state of charge of the battery, adjusting the charging target amount of the battery in a direction to decrease when the power generation device is mounted, and controlling the power supply device while driving based on the adjusted charging target amount.

The power supply device may be an alternator configured to supply charging power to the battery based on the rotational force of the engine.

The power supply device may be a converter configured to supply charging power to the battery by converting a high voltage power of a main battery into low voltage power.

The vehicle may further include a driving detecting sensor configured to detect a driving state of the vehicle, and the determining whether the power generation device is mounted may include determining that the power generation device is mounted when the vehicle is parked and the battery is charged.

The vehicle may further include an illuminance sensor configured to detect illuminance, and a temperature sensor configured to detect external temperature.

The control method may further include controlling to prevent overcharging of the battery when the vehicle is parked and the battery is fully charged.

The controlling to prevent overcharging of the battery may include controlling a switch between the battery and the power generation device to prevent overcharging of the battery.

The controlling to prevent overcharging of the battery may include determining an electric power load based on at least one of the illuminance and the external temperature, and controlling the battery to supply power to the electric power load to prevent overcharging of the battery.

The control method may further include determining an amount of power generation per hour of the power generation device when the vehicle is parked and the battery is charged.

The determining the amount of power generation per hour of the power generation device may include determining the amount of power generation per hour according to at least one of the illuminance and the external temperature.

The adjusting the charging target amount of the battery in a direction to decrease may include adjusting the charging target amount of the battery in a direction to decrease in proportion to the amount of power generation per hour of the power generation device.

The adjusting the charging target amount of the battery in a direction to decrease may include determining an adjustment amount of the charging target amount of the battery based on at least one of the illuminance and the external temperature.

### BRIEF DESCRIPTION OF THE DRAWINGS

These and/or other aspects of the invention will become apparent and more readily appreciated from the following description of the embodiments, taken in conjunction with the accompanying drawings, in which:

FIG. 1 is a control block diagram of a vehicle according to an embodiment of the disclosure.

FIG. 2 is a view illustrating the power flow of a vehicle according to an embodiment of the disclosure.

FIG. 3 is a view illustrating charging by a power generation device when a vehicle according to an embodiment of the disclosure is parked.

FIG. 4 is a flowchart illustrating determining whether a vehicle is equipped with a power generation device among control methods of a vehicle according to an embodiment of the disclosure.

FIG. 5 is a flowchart illustrating a case in which a vehicle prevents overcharging of a battery among control methods of a vehicle according to an embodiment of the disclosure.

FIG. 6 is a flowchart illustrating a case in which a vehicle adjusts a charging target amount of a battery among control methods of a vehicle according to an embodiment of the disclosure.

### DETAILED DESCRIPTION OF ILLUSTRATIVE EMBODIMENTS

Like reference numerals refer to like elements throughout the specification. Not all elements of embodiments of the disclosure will be described, and description of what are commonly known in the art or what overlap each other in the embodiments will be omitted.

It will be understood that when an element is referred to as being “connected” to another element, it can be directly or indirectly connected to the other element, wherein the indirect connection includes “connection” via a wireless communication network.

Also, when a part “includes” or “comprises” an element, unless there is a particular description contrary thereto, the part may further include other elements, not excluding the other elements.

As used herein, the singular forms “a,” “an” and “the” are intended to include the plural forms as well, unless the context clearly indicates otherwise.

As used herein, the terms “portion,” “unit,” “block,” “member,” and “module” refer to a unit that can perform at least one function or operation. For example, these terms may refer to at least one process which is performed by at least one piece of hardware such as a field-programmable gate array (FPGA) and an application specific integrated circuit (ASIC), and at least one piece of software stored in a memory or a processor.

An identification code is used for the convenience of the description but is not intended to illustrate the order of each step. Each of the steps may be implemented in an order different from the illustrated order unless the context clearly indicates otherwise.

Hereinafter, embodiments of a vehicle and a method of controlling the vehicle according to an aspect will be described in detail with reference to the accompanying drawings.

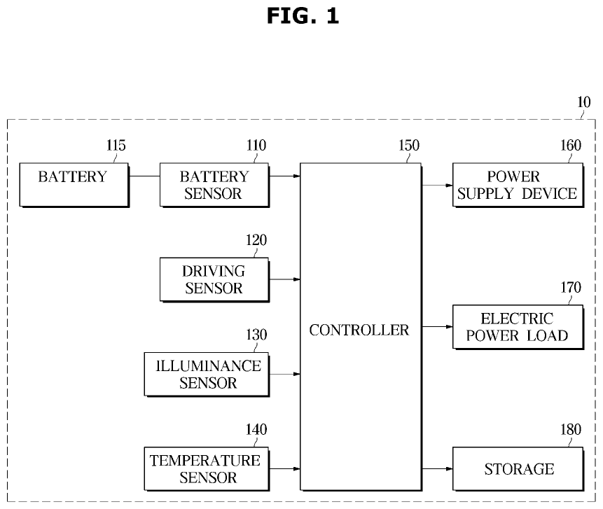

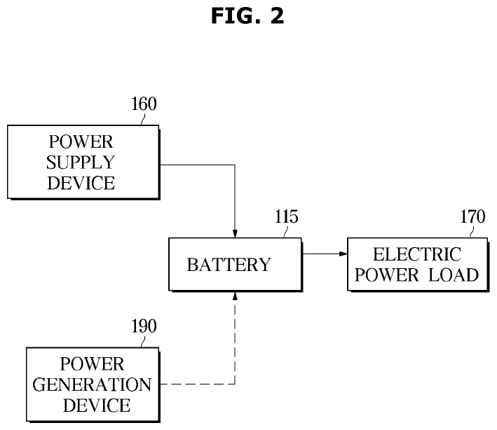

FIG. 1 is a control block diagram of a vehicle according to an embodiment of the disclosure. FIG. 2 is a view illustrating the power flow of a vehicle according to an embodiment of the disclosure.

Referring to FIG. 1, the vehicle 10 according to an embodiment includes a battery 115, a battery sensor 110 for sensing the state of charge of the battery 115, a driving detecting sensor 120 that detects the driving state of the vehicle 10, an illuminance sensor 130 for detecting illuminance, a temperature sensor 140 for sensing temperature, a controller 150 for determining whether a power generation device 190 (see FIG. 2) is mounted on the vehicle 10 and for controlling the charge amount of the battery 115, a power supply device 160 for supplying charging power to the battery 115, an electric power load 170 for performing various functions of the vehicle 10, and a storage 180 for storing various information necessary for the vehicle 10. However, each element of the vehicle 10 may be omitted depending on the embodiment.

The battery sensor 110 according to an embodiment may detect a state of charge of the battery 115. Specifically, the battery sensor 110 may detect the charging amount of the battery 115 in real time.

To this end, the battery sensor 110 may include a voltage sensor capable of detecting the voltage of the battery 115, a current sensor capable of sensing the current of the battery 115 and a temperature sensor capable of sensing the temperature of the battery 115.

As such, the battery sensor 110 may detect the state of charge (SOC) of the battery 115 in real time based on at least one of the voltage, current, or temperature of the battery 115.

At this time, the battery 115 is a power storage device capable of supplying IGN power for starting the vehicle 10 or supplying electric power to the electric power load 170 for various functions of the vehicle 10, and may be a lead acid battery or a lithium ion battery. However, the type and number of the battery 115 are not limited.

The driving detecting sensor 120 according to an embodiment may detect a driving state of the vehicle 10. Specifically, the driving detecting sensor 120 may detect whether the vehicle 10 is driving or parked.

To this end, the driving detecting sensor 120 may be an acceleration sensor that measures the acceleration of the vehicle 10, and may be a voltage sensor or a current sensor that senses IGN power.

The illuminance sensor 130 according to an embodiment may detect illuminance in a space in which the vehicle 10 is located. Specifically, the illuminance sensor 130 may detect illuminance according to the amount of sunlight in the space where the vehicle 10 is located. As the illuminance sensor 130, an illuminance sensor of a known type may be used.

The temperature sensor 140 according to an embodiment may sense the temperature of the air outside the vehicle 10. To this end, a temperature sensor of a type previously known as the temperature sensor 140 may be used.

The controller 150 according to an embodiment may determine whether the power generation device 190 is mounted on the vehicle 10. That is, the controller 150 may determine whether the power generation device 190 is mounted based on the state of charge of the battery 115.

Specifically, the controller 150 determines whether the vehicle 10 is parked based on the output of the driving detecting sensor 120, and determines that the power generation device 190 is mounted when the vehicle 10 is parked and the battery 115 is charged.

As shown in FIG. 2, the battery 115 may be charged by the power supply device 160 when the vehicle 10 is driving. That is, the battery 115, when there is no power generation device 190 for energy harvesting, cannot be charged during parking.

The controller 150 determines that the power generation device 190 is mounted when the battery 115 is charged during parking by using the point that the battery 115 is charged during parking when there is a power generation device 190.

At this time, the power generation device 190 is a device capable of generating electrical energy using natural energy. For example, the power generation device 190 may include a solar panel that converts solar energy into electrical energy, a thermoelectric element that regenerates engine waste heat into electrical energy and an electromagnetic induction device that regenerates the reciprocating motion of the suspension shock absorber into electrical energy. Hereinafter, for convenience of description, the power generation device 190 is described as a solar panel, but the type of the power generation device 190 is not limited thereto.

However, the controller 150 may further consider the output of the illuminance sensor 130 or various switches in order to exclude the case of charging by an external charger.

Specifically, when it is determined that the generation of the power generation device 190 is impossible with the current illuminance based on the output of the illuminance sensor 130, the controller 150 determines the charging is a charging by an external charger. That is, when the output of the illuminance sensor 130 is equal to or less than a preset value, the controller 150 may not determine that the power generation device 190 is mounted.

In addition, the controller 150 determines the charging is a charging by an external charger based on whether a switch corresponding to each of a hood, a trunk, or a door where the battery 115 can be located is operated. That is, the controller 150 may not determine that the power generation device 190 is mounted when any one of the hood, the trunk, or the door where the battery 115 can be located is opened based on whether the switch is operated.

The controller 150 may determine that the power generation device 190 is mounted based on a user input from the input device of the vehicle 10 and may determine that the power generation device 190 is mounted based on the voltage or current of the battery 115 among the outputs of the battery sensor 110.

The controller 150 according to an embodiment may control to prevent overcharging of the battery 115 when the vehicle 10 is parked and the battery 115 is fully charged.

Specifically, the controller 150, when the vehicle 10 is parked and the battery 115 is charged by the power generation device 190, may determine the full charge of the battery 115 based on the output of the battery sensor 110.

At this time, the controller 150 may improve durability reduction of the battery 115 by controlling to prevent overcharging of the battery 115 when the battery 115 is fully charged.

For example, the controller 150 may control a switch between the battery 115 and the power generation device 190 to prevent overcharging of the battery 115. That is, the controller 150 may control the switch so that the battery 115 and the power generation device 190 are opened.

In addition, the controller 150 determines the electric power load 170 based on at least one of illuminance detected by the illuminance sensor 130 and external temperature detected by the temperature sensor 140 and, as shown in FIG. 2, may control the battery 115 to supply electric power to the electric power load 170 so that overcharging of the battery 115 is prevented.

For example, the controller 150 determines the air conditioning device among the electric power load 170 when the external temperature is high, and controls the battery 115 to supply power to the air conditioning device to prevent overcharging of the battery 115.

In addition, the controller 150 determines the seat heating wire among the electric power load 170 when the external temperature is low, and controls the battery 115 to supply power to the seat heating wire, to prevent overcharging of the battery 115.

The controller 150 according to an embodiment may determine the amount of power generation per hour of the power generation device 190 when the vehicle 10 is parked and the battery 115 is charged and may adjust the charging target amount of the battery 115 in a direction to decrease in proportion to the amount of power generation per hour of the power generation device 190.

At this time, the controller 150 may determine and store the amount of power generation per hour according to at least one of illuminance and external temperature.

In addition, the controller 150 may determine an adjustment amount of the charging target amount of the battery 115 based on at least one of illuminance and external temperature. That is, when the amount of light indicated by the illuminance is high or the external temperature is high, the controller 150 may determine to increase the reduction amount of the charging target amount.

Through this, the controller 150 may control the power supply device 160 based on the adjusted charging target amount when the vehicle 10 is driving. Specifically, the controller 150 may control the power supply device 160 to adjust the output voltage for charging the battery 115 in response to the adjusted charging target amount of the battery 115, or may control the power supply device 160 so that the battery 115 is no longer charged when the battery 115 is charged with the adjusted charging target amount.

As such, when the power generation device 190 is mounted on the vehicle 10, the vehicle 10 may improve driving efficiency and power efficiency of the vehicle 10 by reducing the amount of charge to the battery 115 by the power supply device 160 while driving in consideration of charging the battery 115 by the power generation device 190 during parking.

The controller 150 may include at least one memory in which programs for performing the above-described operations and operations described below are stored, and at least one processor for executing the stored programs. In the case of a plurality of memory and processors, it is possible that they are integrated in one chip, and it is also possible to be provided in a physically separate location.

The power supply device 160 according to an embodiment may supply charging power to the battery 115. That is, the power supply device 160 may adjust the output voltage for charging the battery 115 under the control of the controller 150 or stop charging the battery 115.

The power supply device 160 may correspond to an alternator that generates power based on the rotational force of the engine. That is, the power supply device 160 may be an alternator that supplies charging power to the battery 115 based on the rotational force of the engine. As the alternator, a known alternator may be used.

In addition, the power supply device 160 may be a converter that supplies charging power to the battery 115 by converting high voltage power of the main battery that provides high voltage power to the motor to low voltage power when the vehicle 10 corresponds to an eco-friendly vehicle using electric energy, such as a hybrid vehicle and an electric vehicle including a motor that provides power. As the converter, a known converter may be used.

The electric power load 170 according to an embodiment may receive power from the battery 115 under the control of the controller 150.

At this time, the electric power load 170 corresponds to the electrical equipment that performs various functions of the vehicle 10, may include a lamp, an air conditioning device, a heating wire, a black box device and a window adjustment device of the vehicle 10. In addition, any electrical equipment capable of performing various functions of the vehicle 10 may be included without limitation.

The storage 180 according to an embodiment may store various information necessary for the control of the vehicle 10. For example, the storage 180 may store an amount of power generation per hour of the power generation device 190 obtained during parking. At this time, the storage 180 may store an amount of power generation per hour according to at least one of illuminance and external temperature. To this end, as the storage 180, a known storage medium or the like may be used.

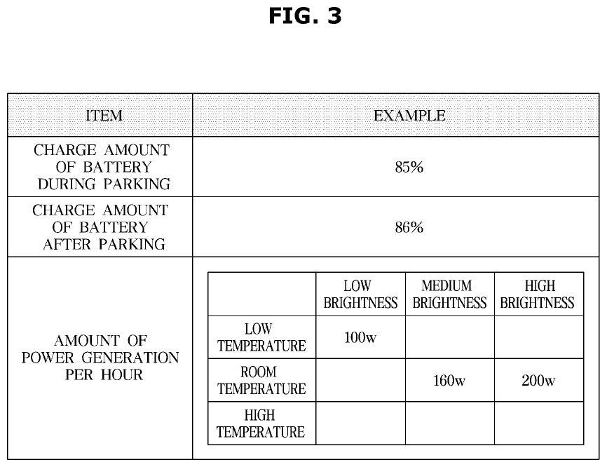

FIG. 3 is a view illustrating charging by a power generation device when a vehicle according to an embodiment of the disclosure is parked.

Referring to FIG. 3, the vehicle 10 according to an embodiment may have a different charge amount of the battery 115 during parking from a charge amount of the battery 115 after parking. For example, the battery 115 may represent a state of charge of 85% during parking, and may represent a state of charge higher than this, e.g., 86%, after parking.

The controller 150 according to an embodiment may determine whether the power generation device 190 is mounted on the vehicle 10. That is, the controller 150 may determine whether the power generation device 190 is mounted based on the state of charge of the battery 115.

Specifically, the controller 150 determines whether the vehicle 10 is parked based on the output of the driving detecting sensor 120 and may determine that the power generation device 190 is mounted when the vehicle 10 is parked and the battery 115 is charged.

The battery 115 may be charged by the power supply device 160 when the vehicle 10 is driving. That is, the battery 115, if there is no power generation device 190 for energy harvesting, cannot be charged during parking.

The controller 150 determines that the power generation device 190 is mounted when the battery 115 is charged during parking by using the point that the battery 115 is charged during parking when there is a power generation device 190.

Therefore, as illustrated in FIG. 3, the controller 150 may determine that the power generation device 190 is mounted on the vehicle 10 when the charge amount of the battery 115 increases after parking.

However, the controller 150 may further consider the output of the illuminance sensor 130 or various switches in order to exclude the case of charging by an external charger.

Specifically, when it is determined that the generation of the power generation device 190 is impossible with the current illuminance based on the output of the illuminance sensor 130, the controller 150 determines the charging is a charging by an external charger. That is, when the output of the illuminance sensor 130 is equal to or less than a preset value, the controller 150 may not determine that the power generation device 190 is mounted.

In addition, the controller 150 determines the charging is a charging by an external charger based on whether a switch corresponding to each of a hood, a trunk, or a door where the battery 115 can be located is operated. That is, the controller 150 may not determine that the power generation device 190 is mounted when any one of the hood, the trunk, or the door where the battery 115 can be located is opened based on whether the switch is operated.

The controller 150 may determine that the power generation device 190 is mounted based on a user input from the input device of the vehicle 10 and may determine that the power generation device 190 is mounted based on the voltage or current of the battery 115 among the outputs of the battery sensor 110.

The controller 150 according to an embodiment may control to prevent overcharging of the battery 115 when the vehicle 10 is parked and the battery 115 is fully charged.

Specifically, the controller 150, when the vehicle 10 is parked and the battery 115 is charged by the power generation device 190, may determine the full charge of the battery 115 based on the output of the battery sensor 110.

At this time, the controller 150 may improve durability reduction of the battery 115 by controlling to prevent overcharging of the battery 115 when the battery 115 is fully charged.

For example, the controller 150 may control a switch between the battery 115 and the power generation device 190 to prevent overcharging of the battery 115. That is, the controller 150 may control the switch so that the battery 115 and the power generation device 190 are opened.

In addition, the controller 150 determines the electric power load 170 based on at least one of illuminance detected by the illuminance sensor 130 and external temperature detected by the temperature sensor 140 and may control the battery 115 to supply electric power to the electric power load 170 so that overcharging of the battery 115 is prevented.

For example, the controller 150 determines the air conditioning device among the electric power load 170 when the external temperature is high, and controls the battery 115 to supply power to the air conditioning device to prevent overcharging of the battery 115.

In addition, the controller 150 determines the seat heating wire among the electric power load 170 when the external temperature is low, and controls the battery 115 to supply power to the seat heating wire, to prevent overcharging of the battery 115.

In addition, the controller 150 according to an embodiment, as shown in FIG. 3, may determine the amount of power generation per hour of the power generation device 190 when the vehicle 10 is parked and the battery 115 is charged and may adjust the charging target amount of the battery 115 in a direction to decrease in proportion to the amount of power generation per hour of the power generation device 190.

For example, the controller 150 may determine a value obtained by subtracting an amount of power generation per hour multiplied by a conversion factor from a preset default charging target amount as an adjusted charging target amount. At this time, the conversion factor may correspond to an efficiency factor when driving, and may be a value reflecting information on a relationship between the charging target amount and the driving efficiency.

At this time, the controller 150 may determine and store the amount of power generation per hour according to at least one of illuminance and external temperature in the storage 180.

In addition, the controller 150 may determine an adjustment amount of the charging target amount of the battery 115 based on at least one of illuminance and external temperature. That is, when the amount of light indicated by the illuminance is high or the external temperature is high, the controller 150 may determine to increase the reduction amount of the charging target amount.

Through this, the controller 150 may control the power supply device 160 based on the adjusted charging target amount when the vehicle 10 is driving. Specifically, the controller 150 may control the power supply device 160 to adjust the output voltage for charging the battery 115 in response to the adjusted charging target amount of the battery 115, or may control the power supply device 160 so that the battery 115 is no longer charged when the battery 115 is charged with the adjusted charging target amount.

That is, when driving, the controller 150 may determine an adjusted charging target amount corresponding to at least one of current illuminance and external temperature among the adjusted charging target amounts stored in the storage 180 and control the power supply device 160 based on the determined charging target amount.

As such, when the power generation device 190 is mounted on the vehicle 10, the vehicle 10 may improve driving efficiency and power efficiency of the vehicle 10 by reducing the amount of charge to the battery 115 by the power supply device 160 while driving in consideration of charging the battery 115 by the power generation device 190 during parking.

Hereinafter, a control method of the vehicle 10 according to an embodiment will be described. The vehicle 10 according to the above-described embodiment may be applied to the control method of the vehicle 10 described later. Therefore, the contents described with reference to FIGS. 1 to 3 are equally applicable to the control method of the vehicle 10 according to an embodiment even if there is no special mention.

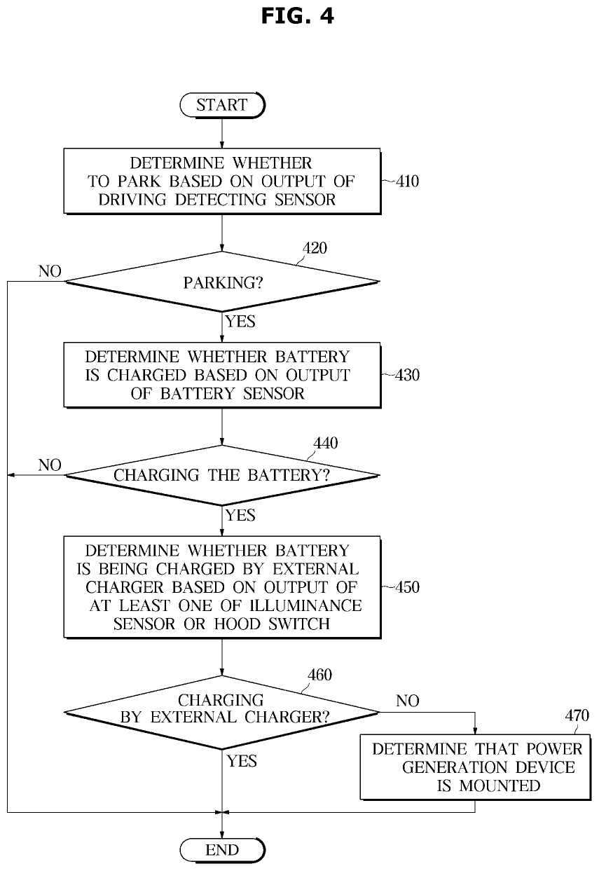

FIG. 4 is a flowchart illustrating determining whether a vehicle is equipped with a power generation device among control methods of a vehicle according to an embodiment of the disclosure.

Referring to FIG. 4, the vehicle 10 according to an embodiment may determine whether to park based on the output of the driving detecting sensor 120 (410), and when the vehicle 10 is parked (YES in 420), may determine whether the battery 115 is charged based on the output of the battery sensor 110 (430).

When the battery 115 is being charged (YES in 440), the vehicle 10 according to an embodiment may determine whether the battery 115 is being charged by an external charger based on the output of at least one of the illuminance sensor 130 or the hood switch (450). When it is not charged by an external charger (NO in 460), it may determine that the power generation device 190 is mounted (470).

That is, the vehicle 10 may determine whether the power generation device 190 is mounted based on the state of charge of the battery 115. However, the vehicle 10 may further consider the output of the illuminance sensor 130 or various switches in order to exclude the case of charging by an external charger.

The vehicle 10 may determine that the power generation device 190 is mounted based on a user input from the input device of the vehicle 10 and may determine that the power generation device 190 is mounted based on the voltage or current of the battery 115 among the outputs of the battery sensor 110.

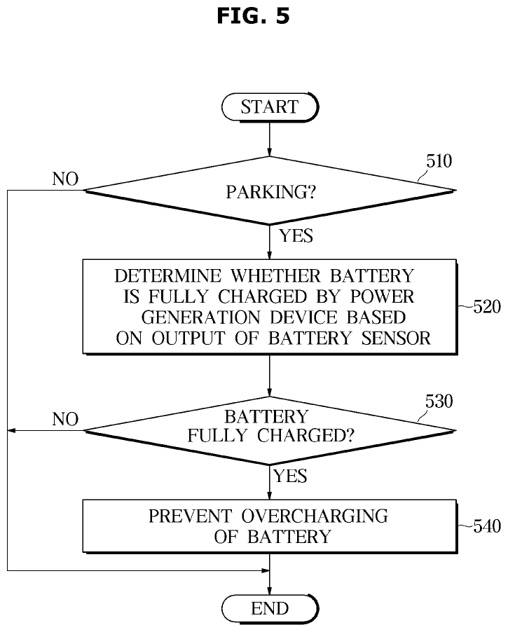

FIG. 5 is a flowchart illustrating a case in which a vehicle prevents overcharging of a battery among control methods of a vehicle according to an embodiment of the disclosure.

Referring to FIG. 5, when parked (YES in 510), the vehicle 10 according to an embodiment may determine whether the battery 115 is fully charged by the power generation device 190 based on the output of the battery sensor 110 (520).

When the battery 115 is fully charged (YES in 530), the vehicle 10 according to an embodiment may prevent overcharging of the battery 115 (540).

For example, the vehicle 10 may control a switch between the battery 115 and the power generation device 190 to prevent overcharging of the battery 115. That is, the vehicle 10 may control the switch so that the battery 115 and the power generation device 190 are opened.

In addition, the vehicle 10 determines the electric power load 170 based on at least one of illuminance detected by the illuminance sensor 130 and external temperature detected by the temperature sensor 140 and may control the battery 115 to supply electric power to the electric power load 170 so that overcharging of the battery 115 is prevented.

For example, the vehicle 10 determines the air conditioning device among the electric power load 170 when the external temperature is high, and controls the battery 115 to supply power to the air conditioning device to prevent overcharging of the battery 115.

In addition, the vehicle 10 determines the seat heating wire among the electric power load 170 when the external temperature is low, and controls the battery 115 to supply power to the seat heating wire, to prevent overcharging of the battery 115.

As described above, the vehicle 10 may improve durability reduction of the battery 115 by controlling to prevent overcharging of the battery 115 when the battery 115 is fully charged.

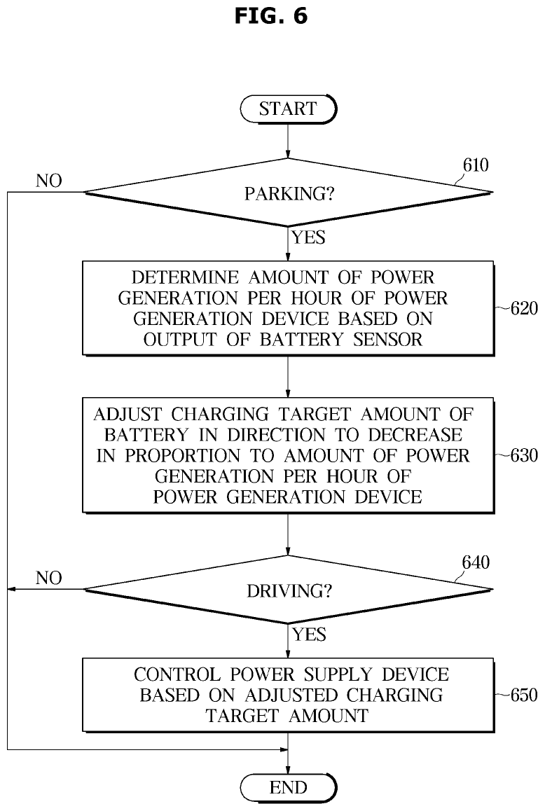

FIG. 6 is a flowchart illustrating a case in which a vehicle adjusts a charging target amount of a battery among control methods of a vehicle according to an embodiment of the disclosure.

Referring to FIG. 6, when the vehicle 10 is parked (YES in 610), the vehicle 10 according to an embodiment may determine the amount of power generation per hour of the power generation device 190 based on the output of the battery sensor 110 (620), and may adjust the charging target amount of the battery 115 in a direction to decrease in proportion to the amount of power generation per hour of the power generation device 190 (630).

At this time, the vehicle 10 may determine and store the amount of power generation per hour according to at least one of illuminance and external temperature.

In addition, the vehicle 10 may determine an adjustment amount of the charging target amount of the battery 115 based on at least one of illuminance and external temperature. That is, when the amount of light indicated by the illuminance is high or the external temperature is high, the vehicle 10 may determine to increase the reduction amount of the charging target amount.

When the vehicle 10 is driving (YES in 640), the vehicle 10 may control the power supply device 160 based on the adjusted charging target amount (650).

Specifically, the vehicle 10 may control the power supply device 160 to adjust the output voltage for charging the battery 115 in response to the adjusted charging target amount of the battery 115, or may control the power supply device 160 so that the battery 115 is no longer charged when the battery 115 is charged with the adjusted charging target amount.

As such, when the power generation device 190 is mounted on the vehicle 10, the vehicle 10 may improve driving efficiency and power efficiency of the vehicle 10 by reducing the amount of charge to the battery 115 by the power supply device 160 while driving in consideration of charging the battery 115 by the power generation device 190 during parking.

According to a vehicle and a control method thereof according to an embodiment of the disclosure, by determining whether a power generation device for energy harvesting is installed, and controlling a battery charge amount, the durability reduction of the battery due to overcharging can be improved, and the power efficiency of the vehicle can be improved.

The computer-readable recording medium may include all kinds of recording media storing commands that can be interpreted by a computer. For example, the computer-readable recording medium may be ROM, RAM, a magnetic tape, a magnetic disc, flash memory, an optical data storage device, etc.

The exemplary embodiments of the disclosure have thus far been described with reference to the accompanying drawings. It will be obvious to those of ordinary skill in the art that the disclosure may be practiced in other forms than the exemplary embodiments as described above without changing the technical idea or essential features of the disclosure. The above exemplary embodiments are only by way of example, and should not be interpreted in a limited sense.

What is claimed is:

1. A vehicle comprising:
a battery;
a power supply device configured to supply charging power to the battery;
a power generation device provided to be detachable;
a battery sensor configured to sense a state of charge of the battery; and
a controller configured to determine whether the power generation device is mounted based on the state of charge of the battery, adjust a charging target amount of the battery in a direction to decrease when the power generation device is mounted and control the power supply device while driving based on the adjusted charging target amount.

2. The vehicle according to claim 1, wherein the power supply device is an alternator configured to supply charging power to the battery based on a rotational force of an engine.

3. The vehicle according to claim 1, wherein the power supply device is a converter configured to supply charging power to the battery by converting a high voltage power of a main battery into low voltage power.

4. The vehicle according to claim 1, further comprising a driving detecting sensor configured to detect a driving state of the vehicle, wherein the controller is configured to determine that the power generation device is mounted when the vehicle is parked and the battery is charged.

5. The vehicle according to claim 4, further comprising:
an illuminance sensor configured to detect illuminance; and
a temperature sensor configured to detect external temperature.

6. The vehicle according to claim 5, wherein the controller is configured to control to prevent overcharging of the battery when the vehicle is parked and the battery is fully charged.

7. The vehicle according to claim 6, wherein the controller is configured to control a switch between the battery and the power generation device to prevent overcharging of the battery.

8. The vehicle according to claim 6, wherein the controller is configured to determine an electric power load based on at least one of the illuminance and the external temperature and to control the battery to supply power to the electric power load to prevent overcharging of the battery.

9. The vehicle according to claim 5, wherein the controller is configured to determine an amount of power generation per hour of the power generation device when the vehicle is parked and the battery is charged.

10. The vehicle according to claim 9, wherein the controller is configured to determine the amount of power generation per hour according to at least one of the illuminance and the external temperature.

11. The vehicle according to claim 9, wherein the controller is configured to adjust the charging target amount of the battery in the direction to decrease in proportion to the amount of power generation per hour of the power generation device.

12. The vehicle according to claim 5, wherein the controller is configured to determine an adjustment amount of the charging target amount of the battery based on at least one of the illuminance and the external temperature.

13. A control method of a vehicle comprising a battery, a power supply device for supplying charging power to the battery, a power generation device provided to be detachable and a battery sensor for sensing a state of charge of the battery, the control method comprising:
determining whether the power generation device is mounted based on the state of charge of the battery;
adjusting a charging target amount of the battery in a direction to decrease when the power generation device is mounted; and
controlling the power supply device while driving based on the adjusted charging target amount.

14. The control method according to claim 13, wherein the power supply device is an alternator and the control method further comprises supplying charging power from the alternator to the battery based on a rotational force of an engine.

15. The control method according to claim 13, wherein the power supply device is a converter and the control method further comprises supplying charging power from the converter to the battery by converting a high voltage power of a main battery into low voltage power.

16. The control method according to claim 15, wherein the vehicle further comprises a driving detecting sensor, the control method further comprising:
detecting a driving state of the vehicle by the driving detecting sensor; and
determining that the power generation device is mounted when the vehicle is parked and the battery is charged.

17. The control method according to claim 16, wherein the vehicle further comprises an illuminance sensor for detecting illuminance and a temperature sensor for detecting external temperature.

18. The control method according to claim 17, further comprising controlling to prevent overcharging of the battery when the vehicle is parked and the battery is fully charged.

19. The control method according to claim 18, wherein controlling to prevent overcharging of the battery comprises controlling a switch between the battery and the power generation device to prevent overcharging of the battery.

20. The control method according to claim 18, wherein controlling to prevent overcharging of the battery comprises:
determining an electric power load based on at least one of the illuminance and the external temperature; and
controlling the battery to supply power to the electric power load to prevent overcharging of the battery.
